(19) United States
(12) Patent Application Publication
(10) Pub. No.: US 2016/0307851 A1
(43) Pub. Date: Oct. 20, 2016

(54) METHOD OF DIVIDING WAFER

(71) Applicant: DISCO CORPORATION, Tokyo (JP)

(72) Inventors: Yukinobu Ohura, Tokyo (JP); Yohei Yamashita, Tokyo (JP); Satoshi Kumazawa, Tokyo (JP)

(21) Appl. No.: 15/131,887

(22) Filed: Apr. 18, 2016

(30) Foreign Application Priority Data
Apr. 17, 2015 (JP) 2015-084923

(51) Int. Cl. H01L 23/544; H01L 21/683; H01L 21/78

(52) U.S. Cl. CPC H01L 23/544; H01L 21/78; H01L 21/6836; H01L 2221/68327; H01L 2221/6834; H01L 2223/5446

(57) ABSTRACT

A method of dividing a wafer includes a protective film forming step of forming a water-soluble protective film on a front side of the wafer, a mask forming step of forming an etching mask on the front side of the wafer by partly removing the water-soluble protective film along the streets, a plasma etching step of performing a plasma etching on the wafer along the streets through the etching mask in the form of the water-soluble protective film, and a protective film removing step of removing the water-soluble protective film by supplying cleaning water to the water-soluble protective film. After plasma etching, i.e. in removing the protective film, the water-soluble protective film can easily be removed from the front side of the wafer simply by supplying the cleaning water from a water supply unit to the water-soluble protective film.

### BACKGROUND OF THE INVENTION

1. Field of the Invention

The present invention relates to a method of dividing a wafer into individual chips.

2. Description of the Related Art

In the process of fabricating devices, a plurality of chip areas are defined on the front side of a wafer by a plurality of division lines arranged in a grid pattern on the front side of the wafer, and devices such as ICs, LSI circuits, etc. are formed in the respective chip areas. The wafer thus arranged is reduced to a predetermined thickness by having its back side ground, and then is divided into chips provided with individual devices, after which the chips are resin-sealed into packages that will be widely used in various electronic instruments including cellular phones, personal computers, etc.

For dividing a wafer, there have been proposed a method of cutting the wafer along division lines with a cutting blade that is rotated and displaced to incise the wafer and a method of applying a laser beam to the wafer along division lines to divide the wafer into individual chips (see, for example, Japanese Patent Laid-open No. Hei 10-305420). There has also been proposed a method of dividing a wafer into individual chips by covering those areas of the front side of the wafer other than the portions corresponding to division lines, with a resist film as an etching mask, and performing plasma etching on areas along the division lines (see, for example, Japanese Patent Laid-open No. 2006-120834).

### SUMMARY OF THE INVENTION

In the case where a wafer is divided into individual devices by plasma etching as described above, the front side of the wafer is coated with a plasma-resistant resist by a resist film forming apparatus, and a mask is formed in an exposure and development step, after which a plasma etching step is performed to form grooves in the wafer along division lines thereon. Subsequently, an ashing step is carried out in an oxygen plasma by an ashing apparatus, thereby ashing the resist film away.

However, since it is necessary to use different apparatus such as the resist film forming apparatus and the ashing apparatus respectively to form the resist film and remove the resist film, as described above, the wafer processing sequence is complex as a whole and highly costly.

Therefore, it is an object of the present invention to provide a method of efficiently dividing a wafer into individual chips.

In accordance with an aspect of the present invention, there is provided a method of dividing a wafer along a plurality of streets formed on a front side thereof with devices formed in respective areas defined on the front side by the streets, including a protective film forming step of forming a water-soluble protective film on the front side of the wafer, a mask forming step of forming an etching mask on the front side of the wafer by partly removing the water-soluble protective film along the streets, a plasma etching step of performing plasma etching on the wafer along the streets through the etching mask, a protective film removing step of removing the water-soluble protective film by supplying cleaning water to the water-soluble protective film, a protective tape adhering step of adhering a protective tape to the front side of the wafer after the protective film removing step, and grinding step of grinding a back side of the wafer.

Preferably, the wafer includes a conductive film along the streets, and the mask forming step includes the step of irradiating the wafer with a laser beam along the streets to remove the conductive film therealong.

Preferably, the wafer-soluble protective film contains fine particles of a metal oxide dispersed therein. The metal oxide may include TiO₂.

In the method of dividing a wafer according to the present invention, after the plasma etching, i.e. in removing the protective film, the water-soluble protective film can be easily removed from the front side of the wafer simply by supplying the cleaning water to the water-soluble protective film. Therefore, various pieces of equipment including a resist film forming apparatus, an asking apparatus, etc. are made unnecessary, and the cost is reduced and the wafer can be divided into individual chips efficiently.

If a conductive film is formed along the streets on the front side of the wafer, then the conductive film is removed by irradiating the wafer with a laser beam along the streets. This makes it possible to divide the wafer smoothly into the individual chips in the plasma etching step.

If fine particles of a metal oxide (e.g., TiO₂) are dispersed in the water-soluble protective film, then since the water-soluble protective film is rendered more absorptive of the laser beam, it is possible to easily remove the water-soluble protective film covering the streets when the mask forming step is carried out. The water-soluble protective film with which the metal oxide is mixed is more resistant to the plasma. Even if the water-soluble protective film with which the metal oxide is mixed is formed to a reduced thickness on the front side of the wafer, performing plasma etching can be well carried out on the wafer.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view depicting a protective film forming step;

FIG. 2 is a cross-sectional view of a wafer on which a water-soluble protective film has been formed;

FIG. 3 is a cross-sectional view depicting a mask forming step;

FIG. 4 is a perspective view depicting a plasma etching apparatus by way of example;

FIG. 5 is a cross-sectional view depicting a plasma etching step;

FIG. 6 is a cross-sectional view depicting a protective film removing step;

FIG. 7 is a perspective view depicting a protective tape adhering step;

FIG. 8 is a perspective view depicting a grinding apparatus; and

FIG. 9 is a cross-sectional view depicting a grinding step.

### DETAILED DESCRIPTION OF THE PREFERRED EMBODIMENT

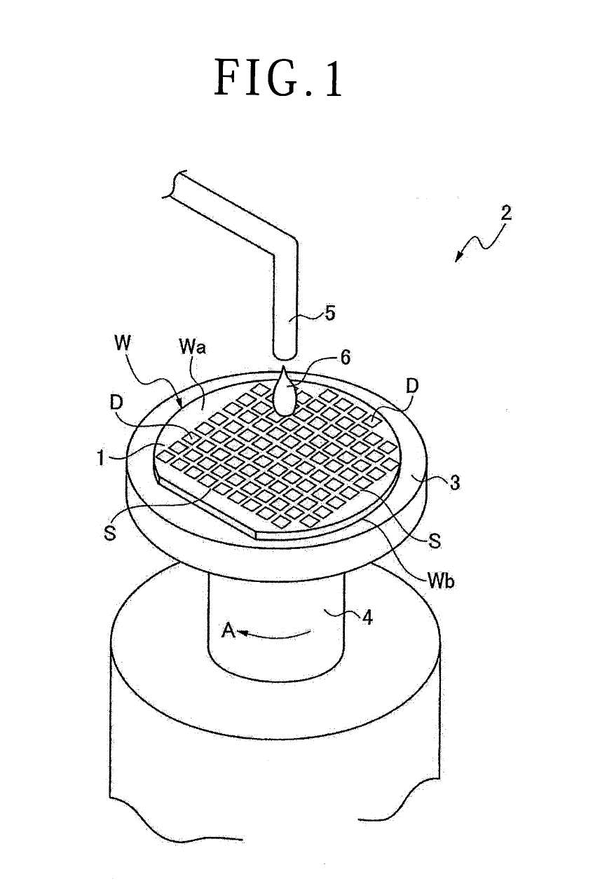

A wafer W depicted in FIG. 1, which represents an example of a workpiece to be processed, has a substrate 1 in the shape of a circular plate. The wafer W has a plurality of streets S formed on a front side Wa thereof and devices D formed in respective areas defined by the streets S. A face of the wafer W which is opposite to the front side Wa is referred to as a back side Wb to be grounded by grinding stones or the like. A method of dividing the wafer W into the individual devices D will be described below.

### (1) Protective Film Forming Step

As depicted in FIG. 1, a water-soluble protective film is formed on the front side Wa of the wafer W using a spin coater 2, for example. The spin coater 2 has a rotatable spinner table 3 that holds the wafer W thereon. A rotational shaft 4 having a vertical axis is connected to the lower side of the spinner table 3. A nozzle 5 for ejecting a material liquid for the water-soluble protective film is disposed above the spinner table 3, and has a tip end directed toward the spinner table 3.

First, the back side Wb of the wafer W is placed on the upper surface of the spinner table 3, with the front side Wa of the wafer W being exposed upwardly, and the spinner table 3 holds the wafer W under suction according to a sucking action of a suction source, not depicted. Thereafter, a motor, not depicted, rotates the rotational shaft 4 about its own axis to rotate the spinner table 3 in the direction indicated by the arrow A while at the same time the tip end of the nozzle 5 is positioned above the central region of the front side Wa of the wafer W held on the spinner table 3 and ejects a liquid resin 6 at a predetermined rate toward the central region.

The liquid resin 6 includes a water-soluble liquid resin such as PVP (polyvinyl pyrrolidone) or PVA (polyvinyl alcohol), for example. Fine particles of a metal oxide should desirably be dispersed and mixed in the liquid resin 6. The metal oxide may be titanium oxide (TiO₂), zinc oxide (ZnO₂), or a transition metal oxide.

Metal oxides having particle diameters sufficiently smaller than the spot size of the liquid resin 6 are appropriate. For example, if the spot size of the liquid resin 6 is in the range from several μm to 1 mm, then the particle diameters of the metal oxide used may be in the range from 10 nm to 50 nm. The concentration of the metal oxide in the liquid resin 6 may be in the range from 1% to 10% or more desirably from 2% to 5%.

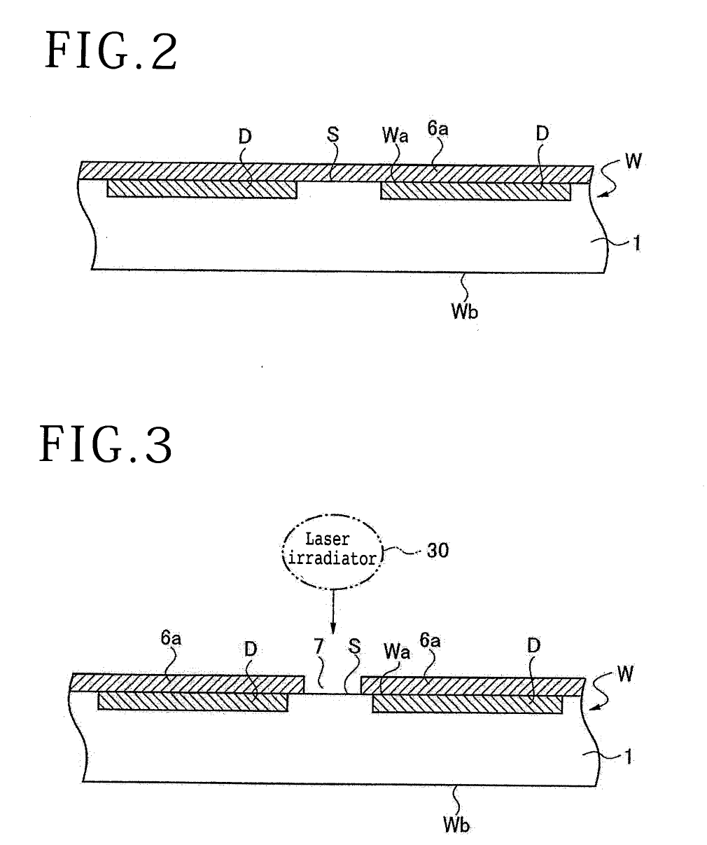

The liquid resin 6 that has dropped onto the front side Wa of the wafer W flows on the front side Wa from the center toward outer peripheral side thereof under centrifugal forces generated by the rotation of the spinner table 3, and spreads entirely over the front side Wa of the wafer W. Thereafter, the spinner table 3 is continuously rotated to deposit the liquid resin 6 to a predetermined thickness on the front side Wa and dry the liquid resin 6. If necessary, the liquid resin 6 on the front side Wa of the wafer W is hardened by baking, for example, thereby forming a water-soluble protective film 6a that covers the front side Wa of the wafer W in its entirety, as depicted in FIG. 2.

### (2) Mask Forming Step

After the protective film forming step has been carried out, as depicted in FIG. 3, the water-soluble protective film 6a is partly removed by a laser irradiator 30 disposed above the wafer W, forming an etching mask. Specifically, after the wafer W has been held on a holder table, not depicted, the laser irradiator 30 irradiates areas of the wafer W which correspond to the streets S depicted in FIG. 1 with a laser beam while the laser irradiator 30 and the holder table are being relatively moved in horizontal directions. The areas which correspond to the streets S may refer to all areas of the streets S or some areas of the streets S.

The mask forming step is carried out under the following processing conditions, for example.

### [Processing Conditions]

Laser beam: YAG/YVO4
Wavelength: 355 nm
Average output: 0.5 W
Repetition frequency: 200 kHz
Irradiation spot diameter: 10 μm
Holder table feed speed: 100 mm/second

When the laser irradiator 30 irradiates the areas of the front side Wa of the wafer W which correspond to the streets S with the laser beam under the above processing conditions, those areas of the water-soluble protective film 6a depicted in FIG. 2 which are present over the streets S are removed, creating openings 7 on the front side Wa of the wafer W. Consequently, the water-soluble protective film 6a which covers at least the devices D remains unremoved in areas of the front side Wa of the wafer W other than the areas corresponding to the streets S. In this manner, an etching mask in the form of the water-soluble protective film 6a is formed on the front side Wa of the wafer W.

If a conductive film such as of a TEG (Test Element Group) or the like is formed along the streets S on the wafer W to be processed, then it is preferable to remove the conductive film together with the water-soluble protective film 6a by irradiating the wafer W with the laser beam along the streets S. This allows a subsequent plasma etching process to be performed efficiently, making it possible to divide the wafer W smoothly into the individual devices D at a later time.

The mask forming step is not limited to being performed by laser beam irradiation, but may be carried out otherwise. For example, the water-soluble protective film 6a may be partly removed along the streets S to form an etching mask on the front side Wa of the wafer W by a cutting blade which rotates and cuts into those areas of the water-soluble protective film 6a which correspond to the streets S.

### (3) Plasma Etching Step

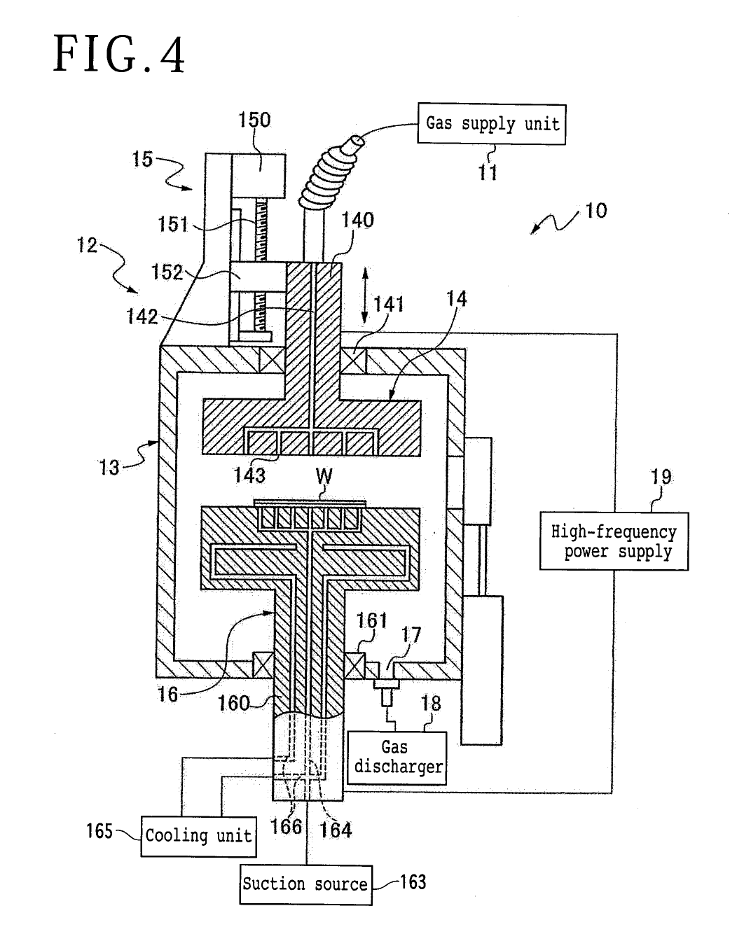

Then, plasma etching is performed on the wafer W through the etching mask. The plasma etching process is carried out by a plasma etching apparatus 10 depicted in FIG. 4, for example. The plasma etching apparatus 10 includes a gas supply unit 11 and an etching processor 12. The gas supply unit 11 stores therein an etching gas including a fluorine such as SF6, CF4, C2F6, C2F4, CHF3, or the like, and an inert gas such as Ar or the like.

The etching processor 12 houses the wafer W therein and etches the wafer W with a plasma of the etching gas supplied from the gas supply unit 11. Specifically, the etching processor 12 includes a chamber 13 for performing plasma etching therein. The chamber 13 houses etching gas supply means 14 in an upper portion thereof and a chuck table 16 for holding the wafer W to be etched in a lower portion thereof.

The etching gas supply means 14 has a function to supply the etching gas to the exposed surface of the wafer W held on the chuck table 16. The etching gas supply means 14 includes a shaft 140 vertically movably inserted through an upper end wall of the chamber 13 and supported by a bearing 141 on the upper end wall of the chamber 13. The etching gas supply means 14 has a gas passageway 142 defined therein which extends through the shaft 140, connected to the gas supply unit 11, and branched into a plurality of ejection ports 143 that are open at the lower end surface of the etching gas supply means 14.

The etching gas supply means 14 can be vertically moved by vertically moving means 15. The vertically moving means 15 includes a motor 150, a ball screw 151 connected to the motor 150, and a vertically movable block 152 having a nut threaded over the ball screw 151. When the motor 150 is energized, the ball screw 151 is rotated about its own axis to vertically move the vertically movable block 152 for thereby vertically moving the etching gas supply means 14.

The chuck table 16 has a shaft 160 rotatably supported by a bearing 161 on a lower end wall of the chamber 13. The chuck table 16 has a suction passageway 164 defined therein which extends through the shaft 160 and connected to a suction source 163 and cooling passageways 166 defined therein which extend through the shaft 160 and connected to a cooling unit 165. The suction passageway 164 is branched into a plurality of ports that are open at the upper end surface of the chuck table 16.

A discharge vent 17 is defined in the lower end wall of the chamber 13 and connected to a gas discharger 18. A used gas is discharged from the chamber 13 through the discharge vent 17 by the gas discharger 18. A high-frequency power supply 19 is electrically connected to the chuck table 16 and the etching gas supply means 14 for applying a high-frequency voltage between the chuck table 16 and the etching gas supply means 14 to convert the etching gas into a plasma in the chamber 13. The high-frequency voltage has a frequency and power selected to be able to dissociate the etching gas into a plasma and obtain a sufficient number of etching species. The plasma etching apparatus 10 includes bias high-frequency voltage supply means, not depicted.

For performing plasma etching on the wafer W using the plasma etching apparatus 10, the wafer W is loaded into the chamber 13 and placed and held on the chuck table 16 with the front side Wa facing upwardly. Then, the etching gas supply means 14 is lowered, and the etching gas is supplied from the gas supply unit 11 into the gas passageway 142. The etching gas is ejected from the ejection ports 143 at the lower end surface of the etching gas supply means 14 into the chamber 13. After the etching gas has been regulated to a predetermined pressure, the high-frequency power supply 19 applies a high-frequency voltage between the chuck table 16 and the etching gas supply means 14 to convert the etching gas into a plasma in the chamber 13. The bias high-frequency voltage supply means applies a bias high-frequency voltage to the wafer W to attract ions to the wafer W, etching the wafer W.

An example of etching conditions is depicted below.

| | | | High-frequency output | | Bias | | Introduced |
|---|---|---|---|---|---|---|---|
| | Time | | for plasma excitation | | output | | gas |
| #1 | 1 | second | 3 | kW | 250 | W | SF₆ |
| #2 | 6 | seconds | 3 | kW | 50 | W | SF₆ |
| #3 | 2 | seconds | 2.5 | kW | 50 | W | C₄F₈ |

The sessions #1 through #3 are repeated in several tens cycles to etch the wafer W.

The frequencies of the high-frequency output for plasma excitation and the bias output are 13.56 MHz.

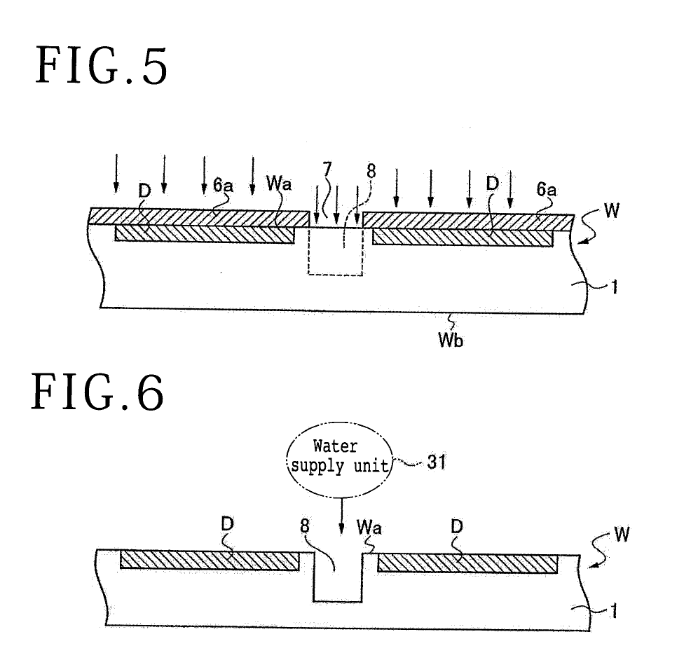

As a result, as depicted in FIG. 5, only an area of the front side Wa of the wafer W which is not covered with the water-soluble protective film 6a, i.e., which lies beneath an opening 7, is etched to form a groove 8 having a desired depth in the wafer W. If a metal oxide is mixed with the water-soluble protective film 6a which covers the front side Wa of the wafer W, then since the water-soluble protective film 6a becomes highly resistant to the plasma, the etching mask is prevented from being unduly reduced in film thickness. Therefore, during the plasma etching process, the water-soluble protective film 6a is prevented from being etched away, exposing the front side Wa of the wafer W. The plasma etching process is finished when a preset time has elapsed and the wafer W has been etched until the groove 8 has been formed to a predetermined depth.

### (4) Protective Film Removing Step

Then, the water-soluble protective film 6a covering the front side Wa of the wafer W as depicted in FIG. 5 is removed. Specifically, as depicted in FIG. 6, a water supply unit 31 disposed above the wafer W supplies cleaning water to the front side Wa of the wafer W. The water-soluble protective film 6a is dissolved away by the cleaning water, leaving the front side Wa of the wafer W exposed. The cleaning water may compose pure water.

### (5) Protective Tape Adhering Step

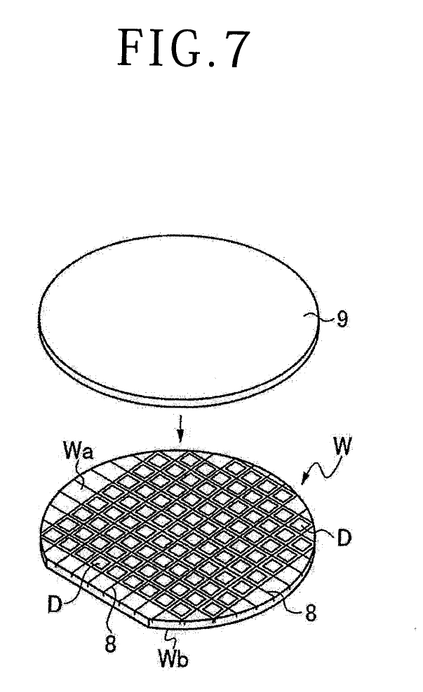

After the protective film removing step has been carried out, as depicted in FIG. 7, a protective tape 9 is adhered to the front side Wa of the wafer W. The wafer W and the protective tape 9 are integrally combined to protect the devices D at the time the wafer W is ground as described below. The protective tape 9 is not limited to any particular material, but may compose an adhesive tape, for example.

### (6) Grinding Step

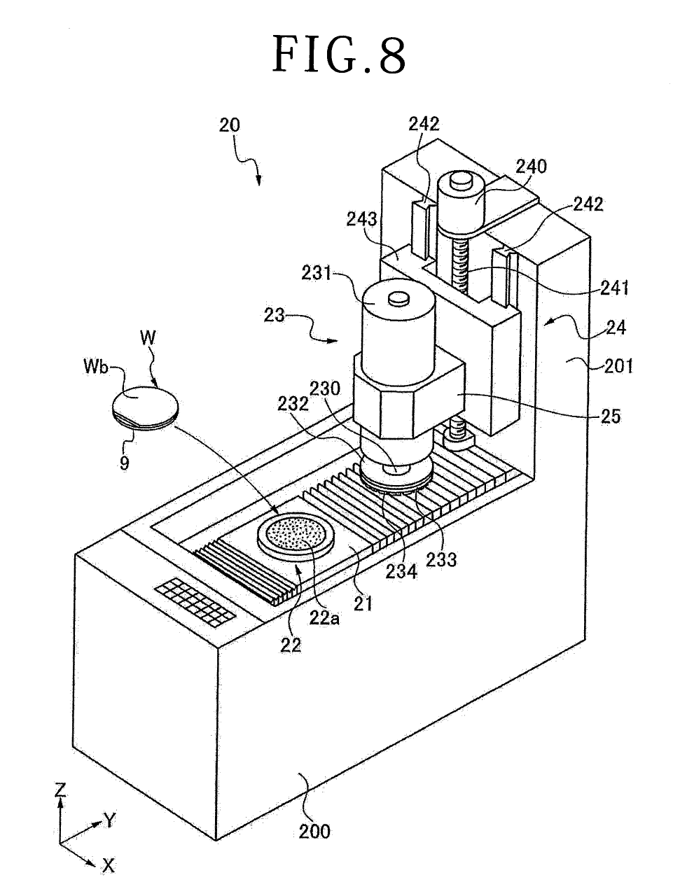

The back side Wb of the wafer W is ground to make the wafer W thinner. The wafer W may be ground by a grinding apparatus 20 depicted in FIG. 8, for example. The grinding apparatus 20 includes an apparatus base 200 extending in a Y-axis direction and a column 201 erected in a Z-axis direction on a rear portion of the apparatus base 200 in the Y-axis direction. A chuck table 22 having a holding surface 22a for holding the wafer W thereon is disposed on the apparatus base 200. The chuck table 22 has its periphery covered by a cover 21, and the chuck table 22 and the cover 21 are reciprocally movable along the Y-axis direction.

Grinding means 23 for grinding the wafer W is mounted on a side of the column 201 by grinding feed means 24. The grinding means 23 includes a spindle 230 having an axis extending along the Z-axis direction, a spindle housing 231 housing the spindle 230 rotatably therein, a grinding wheel 233 mounted on the lower end of the spindle 230 by a mount 232, and a plurality of grinding stones 234 fixed in an annular pattern to a lower surface of the grinding wheel 233. The grinding means 23 includes a motor, not depicted, for rotating the grinding wheel 233 about its own axis at a predetermined rotational speed.

The grinding feed means 24 includes a ball screw 241 extending in the Z-axis direction, a motor 240 connected to one end of the ball screw 241, a pair of guide rails 242 extending parallel to the ball screw 241 and disposed one on each side of the ball screw 241, and a vertically movable block 243 having a surface coupled to a support 25 on which the spindle housing 231 is supported. The vertically movable block 243 has an opposite surface held in sliding contact with the guide rails 242 and a nut centrally disposed thereon which is threaded over the ball screw 241. When the motor 240 is energized to rotate the ball screw 241 about its own axis, the vertically movable block 243 is vertically moved in the Z-axis direction along the guide rails 242, vertically moving the grinding means 23 in the Z-axis direction.

For grinding the back side Wb of the wafer W, as depicted in FIG. 8, the back side Wb of the wafer W is exposed upwardly, and the wafer W is placed on the holding surface 22a of the chuck table 22 with the protective tape 9 facing the holding surface 22a, and is held thereon under suction. While the chuck table 22 is being rotated about its own axis, it is moved together with the cover 21 to a position below the grinding means 23.

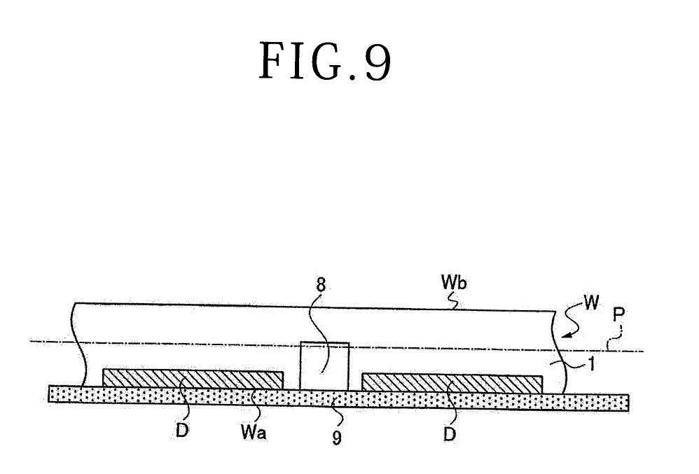

Then, the spindle 230 is rotated about its own axis to rotate the grinding wheel 233, and the grinding feed means 24 lowers the grinding means 23 toward the back side Wb of the wafer W until the rotating grinding stones 234 contact the back side Wb, whereupon the grinding stones 234 start grinding the back side Wb. As depicted in FIG. 9, the grinding feed means 24 feeds the grinding stones 234 downwardly to continuously grind the wafer W to a depth P where at least the groove 8 appears, thereby dividing the wafer W into chips with the individual devices D.

In the method of dividing a wafer according to the present invention, since the etching mask is formed on the front side Wa of the wafer W by the water-soluble protective film 6a, the water-soluble protective film 6a covering the front side Wa of the wafer W can easily be removed simply by supplying cleaning water from the water supply unit 31 to the water-soluble protective film 6a when the protective film removing step is carried out after the plasma etching step has been performed. Therefore, various pieces of equipment including a resist film forming apparatus, an asking apparatus, etc. are made unnecessary, and the wafer processing sequence is simplified and made less costly.

If fine particles of a metal oxide are dispersed and mixed in the water-soluble protective film 6a, then since the water-soluble protective film 6a is rendered more absorptive of the laser beam, it is possible to remove the water-soluble protective film 6a on the streets S efficiently when the mask forming step is carried out.

The water-soluble protective film 6a with which the metal oxide is mixed is more resistant to the plasma than a water-soluble protective film with which no metal oxide is mixed. Even if the water-soluble protective film 6a with which the metal oxide is mixed is formed to a thickness of approximately 4 μm on the front side Wa of the wafer W, the plasma etching step can be well carried out on the wafer W. In addition, the possibility of the water-soluble protective film 6a peeling off the front side Wa of the wafer W during plasma etching is reduced. Furthermore, whereas a water-soluble protective film with which no metal oxide is mixed needs to have a thickness in the range from 10 μm to 20 μm as an etching mask, the water-soluble protective film 6a which contains a metal oxide such as TiO₂ or the like can be of a reduced thickness. Consequently, the cost is reduced, and the removal of the water-soluble protective film 6a is facilitated in the protective film removing step.

According to the present embodiment, it has been described that the grinding step to grind the back side Wb of the wafer W is carried out after the plasma etching step has been performed. However, the wafer W may be divided into individual chips by plasma etching after the wafer W has been ground to a desired thickness. Specifically, after the protective tape adhering step and the grinding step have been carried out successively to grind the back side Wb of the wafer W so that the wafer W has a desired thickness, the protective film forming step and the mask forming step may be carried out successively to form an etching mask in the form of a water-soluble protective film on the front side Wa. Then, the plasma etching step may be carried out to fully sever the wafer W that has been thinned into individual chips. In this case, too, the front side Wa of the wafer W that has been subjected to the plasma etching may be supplied with cleaning water to remove the water-soluble protective film with ease.

Furthermore, after the laser beam has been focused in the wafer W along the streets S to form a modified layer therein, the protective film forming step, the mask forming step, the plasma etching step, and the protective film removing step may be carried out successively. In this case, grooves having a desired thickness reaching the modified layer may be formed to divide the wafer W in the plasma etching step, or if necessary, a tape or the like may be adhered to the back side Wb of the wafer W and then may be stretched radially to apply forces tending to expand the wafer W in planar directions, thereby dividing the wafer W into chips provided with individual devices D.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A method of dividing a wafer along a plurality of streets formed on a front side with devices formed in respective areas defined on the front side by the streets, comprising:
a protective film forming step of forming a water-soluble protective film on the front side of the wafer;
a mask forming step of forming an etching mask on the front side of the wafer by partly removing the water-soluble protective film along the streets;
a plasma etching step of performing plasma etching on the wafer along the streets through the etching mask;
a protective film removing step of removing the water-soluble protective film by supplying cleaning water to the water-soluble protective film;
a protective tape adhering step of adhering a protective tape to the front side of the wafer after the protective film removing step; and
a grinding step of grinding a back side of the wafer.

2. The method according to claim 1, wherein the wafer includes a conductive film along the streets; and
the mask forming step includes the step of irradiating the wafer with a laser beam along the streets to remove the conductive film.

3. The method according to claim 1, wherein the wafer-soluble protective film contains fine particles of a metal oxide dispersed.

4. The method according to claim 3, wherein the metal oxide includes TiO₂.
